(19) United States
(12) Patent Application Publication
(10) Pub. No.: US 2006/0017166 A1
(43) Pub. Date: Jan. 26, 2006

(54) Robust fluorine containing Silica Glass (FSG) Film with less free fluorine

(76) Inventors: Po-Hsiung Leu, Lujhu Township (TW); Harry Chuang, Hsin-Chu (TW); Ying-Hsiu Tsai, Hsin-Chu (TW); Shu-Tine Yang, Hsin-Chu (TW); Cheng-Hui Yang, Hsin-Chu (TW); Chung-Ming Feng, Hsinchu City (TW); Szu-An Wu, Hsin-Chu (TW); Tsang-Yu Liu, Hsin-Chu (TW); Ming-Te Chen, Hsin-Chu (TW)

Correspondence Address: SLATER & MATSIL, L.L.P., 17950 PRESTON ROAD, SUITE 1000, DALLAS, TX, 75252, US

(21) Appl. No.: 10/929,751

(22) Filed: Aug. 30, 2004

Related U.S. Application Data
(60) Provisional application No. 60/589,240, filed on Jul. 20, 2004.

(51) Int. Cl. H01L 23/52

(52) U.S. Cl. 257/758

(57) ABSTRACT

A semiconductor device and method of manufacture thereof having a less free fluorine (F) fluorine containing Silica Glass (FSG) dielectric film formed thereon. The FSG dielectric film includes about 25% or less free F, has a porosity of about 5% or less and has a dielectric constant of about 3.8 or less. A first barrier layer may be disposed between a workpiece and the FSG dielectric film, and a second barrier layer may be disposed between the FSG dielectric film and at least one conductive line formed in the FSG dielectric film. The FSG dielectric film is formed by introducing SiF₄:SiH₄ at a reaction condition ratio of about 2.5 or less at a pressure of about 3 Torr or less and at an RF of about 500 watts to 5000 watts.

This application claims the benefit of U.S. Provisional Application No. 60/589,240, filed on Jul. 20, 2004, entitled “Robust Fluorinated Silica Glass (FSG) Film with Less Free Fluorine,” which application is hereby incorporated herein by reference.

### TECHNICAL FIELD

The present invention relates generally to the fabrication of semiconductor devices, and more particularly to the formation of fluorine containing dielectric films.

### BACKGROUND

Semiconductor devices are fabricated by depositing and patterning one or more conductive, insulating, and semiconductor layers to form integrated circuits. Some integrated circuits have multiple layers (or multilevels) of interconnect. The dielectric layers between metal levels are referred to in the art as inter-metal dielectrics (IMD's). Using multilevel interconnects results in the ability to manufacture more die per wafer.

As semiconductor devices are scaled down in size, the propagation delay, or the RC delay, becomes a concern. To reduce this delay, there is a trend in the semiconductor industry towards the use of low dielectric constant (k) materials, which reduce the capacitance between conductive lines, as insulating layers between interconnects.

One low k material used in semiconductor manufacturing is fluorine containing silica glass (FSG). Fluorine containing dielectric films are silicon oxyfluorides (FₓSiO_{y}) or carbon doped silicon oxyfluorides, or other impurity doped silicon oxyfluorides, deposited by chemical vapor deposition (CVD). FSG has a dielectric constant k value of about 3.8 or lower, depending on the amount of fluorine (F), which is lower than the k value of silicon dioxide (SiO₂), for example. FSG dielectric films are formed in plasma enhanced CVD (PECVD) or high density plasma CVD (HDP-CVD) tools by adding SiF₄ to the process gas ambient used to deposit SiO₂ by CVD (silane and oxygen). For carbon doped silicon oxyfluorides, carbon containing gases such as CO, or CO₂ may be added.

By increasing the SiF₄ flow rate, more F is incorporated into an FSG dielectric film. Higher concentrations of F cause the value of k to decrease. However, a maximum of about 6% F may be incorporated into the FSG dielectric films (e.g., chemically bonded to silicon) because higher concentrations cause F to be evolved during reactive ion etch (RIE) of these films. The evolution of F from the FSG oxide is a problem when used in copper interconnect systems, for example, because the F readily attacks Ta-based liners of the copper interconnects, leading to volatile TaF₂ formation and resulting in the loss of adhesion between the low-k film and the Ta liners. FSG dielectric films with a high F concentration have been shown to be unstable, resulting in blistering after depositing a cap layer and/or metal layer, and also after passivation and metallization alloying treatments.

Another problem with prior art FSG dielectric films is that they are porous, being greater than about 5% porous (defined as 5%⁺ for following description), which causes the FSG dielectric films to be unstable. For example, a comparison of an etching rate of a prior art porous FSG film to a thermal oxide film in 50:1 HF or 100:1 HF at a temperature of about 21 degrees C. to about 75 degrees C. results in a 5%+porous FSG film etching at a rate of about 20 times of etching rate of a thermal oxide film. For example, a 5%⁺ porous FSG film has an etching rate of about 800 Angstroms/min in 50:1 HF, while the etching rate of a thermal oxide is about 40 Angstroms/min in the same conditions. The use of prior art FSG dielectric films in semiconductor devices can result in metal shorts or metal bridging, high leakage current between metal, and stress migration failures.

Therefore, what is needed in the art is an improved FSG dielectric film that is compatible with and is stable when used with copper and other metal interconnect systems.

### SUMMARY OF THE INVENTION

These and other problems are generally solved or circumvented, and technical advantages are generally achieved, by preferred embodiments of the present invention, in which deposition parameters are selected such that a less porous FSG dielectric film having less free F is deposited and formed on a semiconductor wafer.

In accordance with a preferred embodiment of the present invention, a semiconductor device includes a workpiece, and a fluorine containing dielectric film formed over the workpiece, wherein the fluorine containing dielectric film comprises a wet etching rate ratio to a thermal oxide of less than about 15 by HF.

In accordance with another preferred embodiment of the present invention, a semiconductor device includes a workpiece, a device formed within the workpiece, and a fluorine containing dielectric film formed over the workpiece. The fluorine containing dielectric film comprises a wet etching rate of less than about 300 Å/minute by 100:1 HF at a temperature of about 21 degrees C. to about 75 degrees C. and a dielectric constant of about 3.8 or less. At least one conductive line is disposed within the fluorine containing dielectric film.

In accordance with yet another preferred embodiment of the present invention, a method of fabricating a semiconductor device includes providing a workpiece, and forming a fluorine containing dielectric film over the workpiece, wherein the fluorine containing dielectric film comprises about 25% or less free F.

Advantages of embodiments of the invention include providing a fluorine containing dielectric film for use as a dielectric material layer in semiconductor devices that has less free F and is compatible with the conductive materials used in modern interconnect systems. The fluorine containing dielectric film is less porous, is more stable and has an improved film quality than prior art FSG dielectric films. Semiconductor devices using the novel fluorine containing dielectric film have improved electrical performance, such as reduced contact resistance of vias (Rc-Via).

The foregoing has outlined rather broadly the features and technical advantages of embodiments of the present invention in order that the detailed description of the invention that follows may be better understood. Additional features and advantages of embodiments of the invention will be described hereinafter, which form the subject of the claims of the invention. It should be appreciated by those skilled in the art that the conception and specific embodiments disclosed may be readily utilized as a basis for modifying or designing other structures or processes for carrying out the same purposes of the present invention. It should also be realized by those skilled in the art that such equivalent constructions do not depart from the spirit and scope of the invention as set forth in the appended claims.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1a is a cross-sectional view of a semiconductor device comprising a novel less free F fluorine containing FSG dielectric film in accordance with an embodiment of the present invention;

FIG. 1b is a more detailed view of the optional barrier layers shown in FIG. 1a;

FIG. 2 is a cross-sectional view of another semiconductor device comprising the less free F fluorine containing FSG dielectric film of embodiments of the present invention;

FIG. 3 shows FTIR spectrum test results of a prior art FSG dielectric film and the less free F FSG dielectric film in accordance with an embodiment of the present invention;

FIGS. 4a and 4b show TDS test results for a prior art FSG dielectric film and for the less free F FSG dielectric film in accordance with an embodiment of the present invention over a range of partial pressures and temperatures; and

FIG. 5 shows a SIMS comparison between a prior art FSG dielectric film and a fluorine containing dielectric film in accordance with an embodiment of the present invention.

Corresponding numerals and symbols in the different figures generally refer to corresponding parts unless otherwise indicated. The figures are drawn to clearly illustrate the relevant aspects of the preferred embodiments and are not necessarily drawn to scale.

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

The present invention will be described with respect to preferred embodiments in a specific context, namely a fluorine containing or FSG dielectric film having less free F formed on a semiconductor substrate or workpiece. Embodiments of the invention may also be applied, however, to other applications and technologies where dielectric materials are used.

Free fluorine, or fluorine that has not bonded chemically with silicon, is found in a high percentage in prior art FSG dielectric films. For example, prior art FSG dielectric films may comprise greater than about 30% free F. The free F in FSG dielectric films typically exists in an ion state as F−. The high percentage of free F in these FSG dielectric films causes these FSG dielectric films to be very porous, e.g., having a porosity of greater than about 5%. The high porosity makes the prior art FSG dielectric films unstable for use as dielectric materials in semiconductor devices, and may cause metal-metal shorts, unpredictability in etching processes, and device failures.

In accordance with embodiments of the present invention, a fluorine containing dielectric film is formed that has less free F. Because there is less free F in the fluorine containing dielectric film, the novel less free F fluorine containing dielectric film is more stable and is less porous than prior art FSG dielectric films. Preferably, the less free F fluorine containing dielectric film formed in accordance with embodiments of the present invention comprises about 25% free F or less, which is significantly less than the amount of free F in prior art FSG dielectric films. More preferably, the fluorine containing dielectric film comprises about 20% free F or less, in one embodiment.

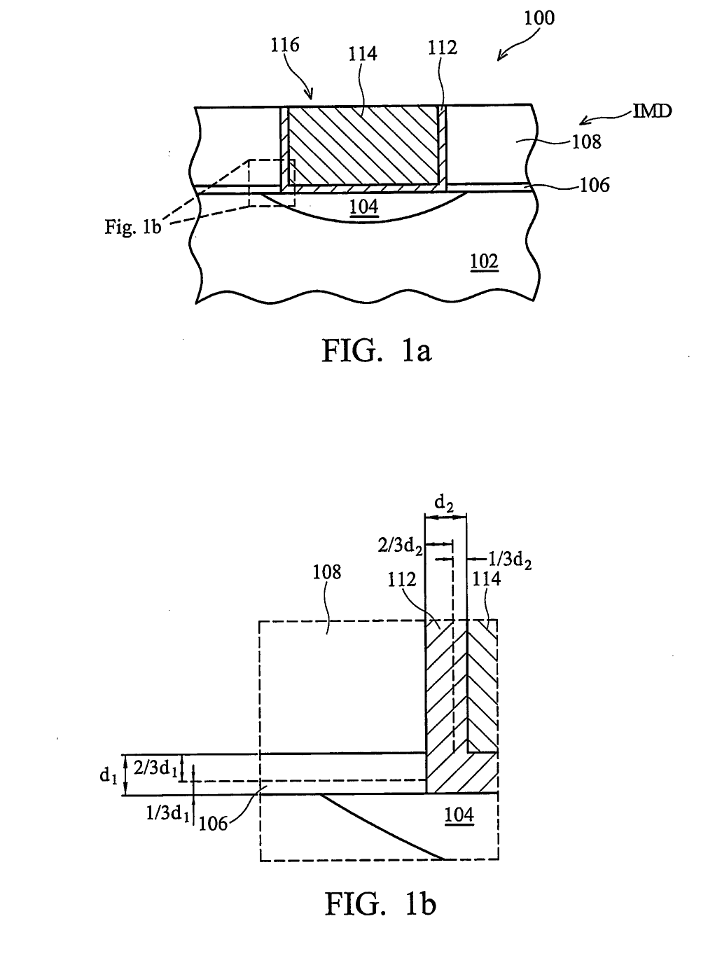

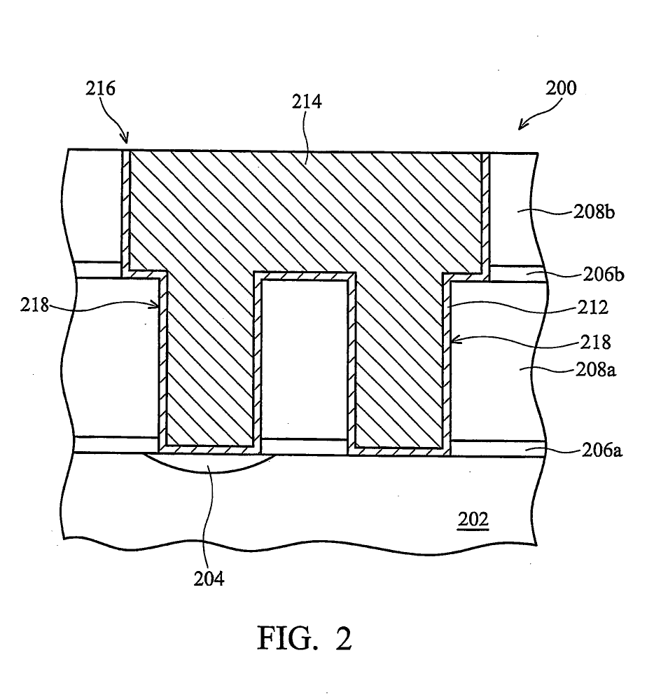

The deposition parameters of the less free F fluorine containing dielectric film in accordance with preferred embodiments will next be described. Referring to FIG. 1a, a workpiece 102 is provided. The workpiece 102 may include a semiconductor substrate comprising silicon or other semiconductor materials covered by an insulating layer, for example. The workpiece 102 may also include other active components or circuits 104 formed therein. The workpiece 102 may comprise silicon oxide over single-crystal silicon, for example. The workpiece 102 may include other conductive layers or other semiconductor elements, e.g. transistors, diodes, etc. Compound semiconductors, GaAs, InP, Si/Ge, or SiC, as examples, may be used in place of silicon.

An optional first diffusion barrier layer 106 may be formed on the top surface of the workpiece 102, as shown. The first diffusion barrier layer 106 is adapted to prevent or minimize the diffusion of impurities from the less free F fluorine containing dielectric film 108 into the workpiece 102, and also to prevent or minimize the diffusion of impurities from the workpiece 102 into the less free F fluorine containing dielectric film 108, for example.

The first diffusion barrier layer 106 preferably comprises a dielectric or insulating material, in a preferred embodiment. The first diffusion barrier layer 106 may comprise nitrogen-containing materials such as silicon nitride, silicon oxynitride, silicon carbon nitride, tantalum nitride, titanium nitride, or tungsten nitride, as examples. The first diffusion barrier layer 106 may alternatively comprise carbon-containing materials such as silicon carbine (e.g., SiC), silicon carbon oxide (e.g., SiOC), or silicon carbon nitride (e.g., SiCN), for example. Alternatively, the optional first diffusion barrier layer 106 may comprise other insulating materials or combinations of the previously mentioned insulating materials, for example. The optional first diffusion barrier layer 106 preferably comprises a thickness of about 600 Å or less, for example, although alternatively, the first diffusion barrier layer 106 may comprise other dimensions. In some applications, a first diffusion barrier layer 106 is not required.

The semiconductor workpiece 102 is placed into a deposition chamber, and a reactant gas and ambient gases are introduced into the chamber to form a less free F fluorine containing dielectric film 108 directly over the top surface of the workpiece 102, or over the top surface of the first diffusion barrier layer 106, if a first diffusion barrier layer 106 is used. The less free F fluorine containing dielectric film 108 is also referred to herein as a less free F FSG dielectric film 108 or a fluorine containing dielectric film 108, and these terms are used interchangeably herein. A reactant gas comprising SiF₄:SiH₄ is preferably introduced into the chamber at a reaction condition ratio of about 2.5 or less to form the less free F FSG dielectric film 108. In one embodiment, SiF₄:SiH₄ is deposited at a ratio of about 1.6 or less. The pressure in the deposition chamber during the deposition process is preferably about 3 Torr or less, and in one embodiment, the deposition pressure is about 1.2 Torr. The radio frequency (RF) applied to the deposition chamber is preferably about 500 watts to 5000 watts. The less free F FSG dielectric film 108 formed preferably comprises a thickness of about 2,000 Å to about 15,000 Å, as examples, although alternatively, the less free F FSG dielectric film 108 may comprise other dimensions.

The less free F FSG dielectric film 108 may be deposited by plasma enhanced chemical vapor deposition (PECVD) or high-density plasma CVD (HDP CVD), as examples, although alternatively, other deposition methods may be used. Ambient gases in the deposition chamber during the deposition process may include N₂O at a flow rate of about 5000 to about 15,000 standard cubic centimeters per minute (sccm), for example. Other gases may be entered into the deposition chamber during the deposition process. These other gases may include an oxygen based gas or oxygen-containing gas, such as NO, NO₂, CO, O₃, O₂ or CO₂, as examples, although alternatively, other oxygen-containing gases may be used.

Some material properties of the less free F FSG dielectric film 108 formed in accordance with embodiments of the present invention will next be described. The less free F FSG dielectric film 108 produced preferably has a wet etching rate of less than about 300 Å/minute by 100:1 HF (e.g., wherein the volume of HF: H₂O is substantially equal to 100: 1), or less than about 700 Å/minute by 50:1 HF at temperature of about 21 degrees C. to about 75 degrees C. The less free F FSG dielectric film 108 preferably comprises a wet etching rate ratio to a thermal oxide less than about 15, preferably of about 6 to about 10 by HF, in the same conditions as described above. For example, the less free F FSG dielectric film 108 preferably has an etch rate of about 15 times or less than the etch rate of a thermal oxide in HF; e.g., if a thermal oxide has an etching rate of 40 Angstroms/minute, the less free FSG dielectric film 108 preferably has an etch rate of 600 Angstroms/minute or less, and in another embodiment, preferably has an etch rate of about 240 to 600 Angstroms/minute, in the same etching conditions as the thermal oxide etch process.

The less free F FSG dielectric film 108 preferably has a low nitrogen (N) concentration, e.g., of about 1000 counts/second (c/s) or less, in one embodiment. The less free F FSG dielectric film 108 preferably has a dielectric constant of about 3.8 or less, in one embodiment.

The less free F FSG dielectric film 108 preferably has a low out-gassing rate, e.g., a partial pressure of Fluorine of less than about 5×10⁻⁸ Torr at a temperature of about 25 to 400° C. in a chamber with a base pressure of less than about 1×10⁻⁴ mTorr (e.g., in a vacuum environment) using a time domain spectrum (TDS) measurement method, in one embodiment. For example, the out-gassing rate of the less free F FSG dielectric film 108 in test results indicated an out-gassing rate of a Fluorine partial pressure by TDS of less than 4×10⁻⁷ Torr between about 25 to 400° C. at a test condition temperature ramp rate of 2 degrees/minute. In another test, the Fluorine out-gassing rate of the less free F FSG dielectric film 108 by TDS was found to be less than 5×10⁻⁹ Torr/min between about 100 to 200° C. at a test condition temperature rate of 2 degrees/minute.

The measured partial pressure of Fluorine is strongly dependent on sample size and film thickness, as well. In this case, the thickness of the less free F FSG dielectric film 108 is about 5000 Angstroms on a 300 mm workpiece. The less free F FSG dielectric film 108 has a porosity of about 5% or less in accordance with a preferred embodiment of the invention. The low porosity results in improved in structural stability for the less free F FSG dielectric film 108.

After the less free F FSG dielectric film 108 is deposited, the less free F FSG dielectric film 108 may be patterned, e.g., in a damascene process, with a pattern for at least one conductive line 116, as shown in FIG. 1a. Lithography techniques may be used to pattern the less free F FSG dielectric film 108. For example, a photoresist (not shown) may be deposited over the less free F FSG dielectric film 108, and the photoresist may be patterned using a lithography mask. Portions of the photoresist are removed, and portions of the less free F FSG dielectric film 108 may be etched away using the photoresist as a mask. The photoresist may then be stripped or removed from over the less free F FSG dielectric film 108. Alternatively, the less free F FSG dielectric film 108 may be directly etched, using electron beam lithography (EBL) or other direct etching methods, for example.

The less free F FSG dielectric film 108 of the present invention may be pretreated to achieve stable dielectric properties such as dielectric constant, index of refraction, etc., either before or after the less free F FSG dielectric film 108 is patterned. As examples, a surface treatment comprising plasma treatment, a rinse in a base or an acid environment, a thermal treatment, a nitrogen containing ambient treatment, a hydrogen containing ambient treatment, or combinations or a plurality of treatments thereof, may be used. Alternatively, no treatment may be performed, or other types of surface treatments may be used, for example.

After the less free F FSG dielectric film 108 is patterned, an optional second diffusion barrier layer 112 may be deposited or formed over the patterned less free F FSG dielectric film 108, as shown in FIG. 1a. The second diffusion barrier layer 112 is adapted to prevent or minimize the diffusion of impurities from the less free F FSG dielectric film 108 into a subsequently deposited conductive material 114, and also to prevent or minimize the diffusion of impurities from the conductive material 114 into the less free F FSG dielectric film 108 or into the workpiece 102, for example. The use of a second diffusion barrier layer 112 is particularly advantageous when the conductive material 114 comprises copper, for example, because copper easily diffuses into some materials, such as FSG dielectric film.

The second diffusion barrier layer 112 preferably comprises a conductive material and alternatively may comprise an insulating material, for example. The second diffusion barrier layer 112 may comprise nitrogen-containing materials such as silicon nitride, silicon oxynitride, silicon carbon nitride, tantalum nitride, titanium nitride, or tungsten nitride as examples. The second diffusion barrier layer 112 may also comprise carbon-containing materials such as silicon carbine (e.g., SiC), silicon carbon oxide (e.g., SiOC), or silicon carbon nitride (e.g., SiCN), as examples. The second diffusion barrier layer 112 may comprise refractory metal containing materials such as Ta, tantalum nitride (e.g., TaN), Ti, or titanium nitride (e.g., TiN), as examples. Alternatively, the optional second diffusion barrier layer 112 may comprise other insulating materials or combinations of the previously mentioned materials, for example. The second diffusion barrier layer 112 preferably comprises a thickness of about 600 Å or less, for example, although alternatively, the second diffusion barrier layer 112 may comprise other dimensions. In some applications, a second diffusion barrier layer 112 is not required.

A conductive material 114 is deposited over the patterned less free F FSG dielectric film 108 or second diffusion barrier layer 112, if a second diffusion barrier layer 112 is used, as shown in FIG. 1a. The conductive material 114 preferably comprises a conductive material such as copper, aluminum, silver, tungsten, or combinations thereof. Alternatively, the conductive material 114 may comprise other conductive materials, for example. As examples, first conductive material 114 may be formed from any of a variety of suitable conducting materials, including (but not limited to): a metal nitride, a metal alloy, copper, a copper alloy, aluminum, an aluminum alloy, composites thereof, and combinations thereof.

An excess amount (not shown) of the conductive material 114 may reside over a top surface of the less free F FSG dielectric film 108 after the deposition process for the conductive material 114. If present, the excess conductive material 114 is removed from the top surface of less free F FSG dielectric film 108, using a chemical mechanical polish (CMP) process, or by an etch process, leaving at least one first conductive line 116 formed within the less free F FSG dielectric film 108, as shown in FIG. 1a. The at least one first conductive line 116 may comprise a plurality of first conductive lines 116 formed in an IMD layer, not shown.

FIG. 1b shows a more detailed view of the barrier layers 106 and 112 shown in FIG. 1a. The first diffusion barrier layer 106 comprises a first thickness d₁ and the second diffusion barrier layer 112 comprises a second thickness d₂, as shown. In one embodiment, the first diffusion barrier layer 106 preferably has a F diffusion depth of about ⅔ the first thickness d₁ of the first diffusion barrier layer 106. The F concentration in the ⅔ d₁ portion of the first thickness d₁ adjacent and abutting the less free F FSG dielectric film 108 may be about 64% F or less, for example. In this embodiment, preferably, the side of the first diffusion barrier layer 106 that is adjacent and abutting the top surface of the workpiece 102 preferably has a substantially 0% of F concentration for a thickness of ⅓ d₁ or greater.

Similarly, in one embodiment, preferably, the second diffusion barrier layer 112 has a F diffusion depth of about ⅔ the second thickness d₂ of the second diffusion barrier layer 112. The F concentration in the ⅔ d₂ portion of the second thickness d₂ adjacent and abutting the less free F FSG dielectric film 108 may be about 64% F or less, for example. In this embodiment, preferably, the side of the second diffusion barrier layer 112 that is adjacent and abutting the conductive material 114 preferably has a substantially 0% of F concentration for a thickness of about ⅓ d₂ or greater.

Thus, a semiconductor device 100 comprising at least one first conductive line 116 formed in a less free F FSG dielectric film 108 is formed, in accordance with an embodiment of the present invention. In the embodiment shown in FIG. 1a, a single damascene structure and method of fabrication is shown and described herein.

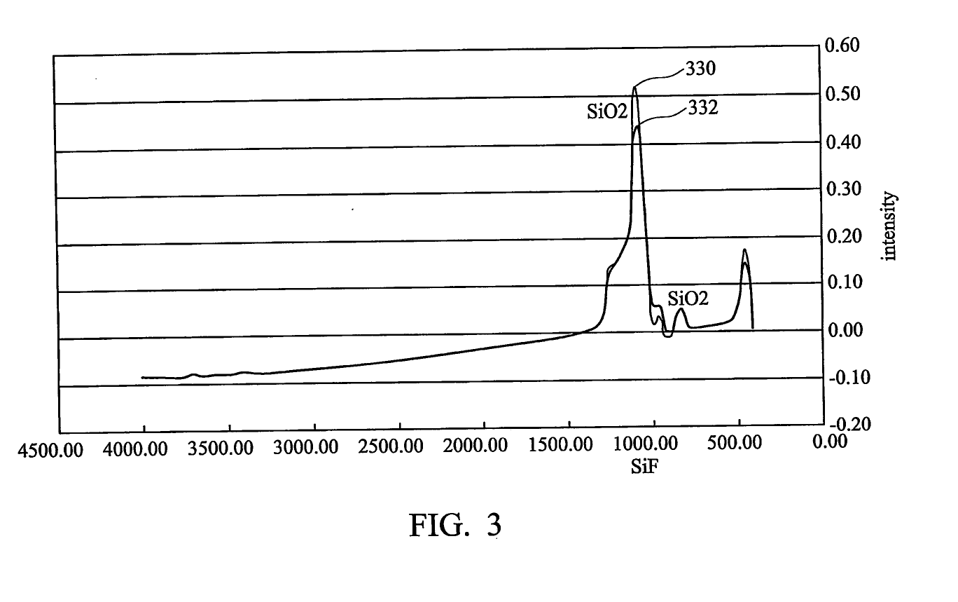

FIG. 2 shows an embodiment of the present invention implemented in a semiconductive device 200 comprising a dual damascene metallization structure. Similar reference numbers are designated for the various elements as were used in FIG. 1a. To avoid repetition, each reference number shown in FIG. 2 is not described again in detail herein. Rather, similar materials x02, x04, x06, etc., are preferably used for the material layers having the same material properties as were described for FIG. 1a, where x=1 in FIG. 1a and x=2 in FIG. 2. As an example, the preferred materials, material properties, and methods of forming thereof, listed for the less free F FSG dielectric film 108 in the description for FIG. 1a are preferably also used for less free F FSG dielectric films 208a and 208b in FIG. 2.

In this embodiment, an optional first diffusion barrier layer 206a is deposited over the workpiece 202, and a less free F FSG dielectric film 208a is formed over the optional first diffusion barrier layer 206a. Another optional first diffusion barrier layer 206b is deposited over the less free F FSG dielectric film 208a, and a less free F FSG dielectric film 208b is formed over the optional first diffusion barrier layer 206b.

A dual damascene manufacturing process is used to pattern the less free F FSG dielectric films 208a and 208b and the optional first diffusion barrier layers 206a and 206b, if used. For example, a first mask (not shown) may first be used to pattern the less free F FSG dielectric film 208b and the optional first diffusion barrier layer 206b with a pattern for at least one conductive line 216, and a second mask (also not shown) may then be used to pattern the less free F FSG dielectric film 208a and the optional first diffusion barrier layer 206a with a pattern for at least one via 218. Alternatively, the second mask may first be used to pattern the less free F FSG dielectric films 208a and 208b and the optional first diffusion barrier layers 206a and 206b with a pattern for at least one via 218, and the first mask may then be used to pattern the less free F FSG dielectric film 208b and the optional first diffusion barrier layer 206b with a pattern for at least one conductive line 216, as shown.

A conductive material 214 is then deposited over the dual damascene patterned materials 206a, 206b, 208a, 208b, and any excess conductive material 214 is removed from over the top surface of the less free F FSG dielectric film 208b, leaving at least one first conductive line 216 and at least one via 218 formed within the diffusion barrier layers 206a and 206b and the less free F FSG dielectric films 208a, 208b, as shown in FIG. 2.

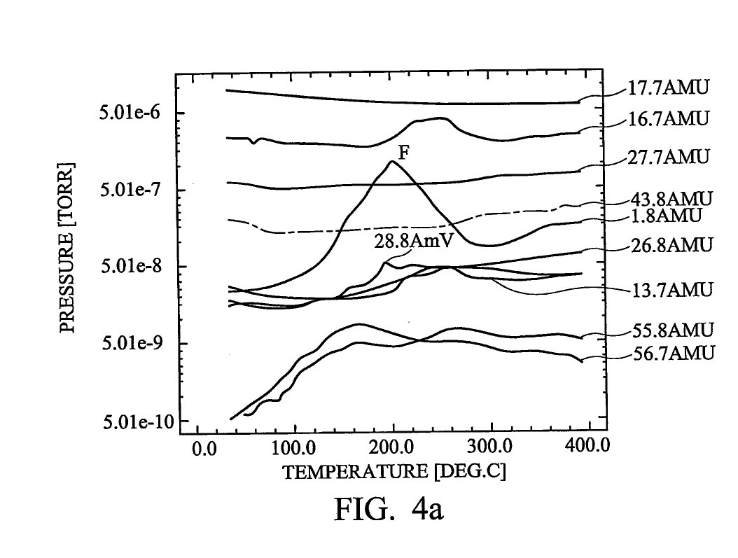

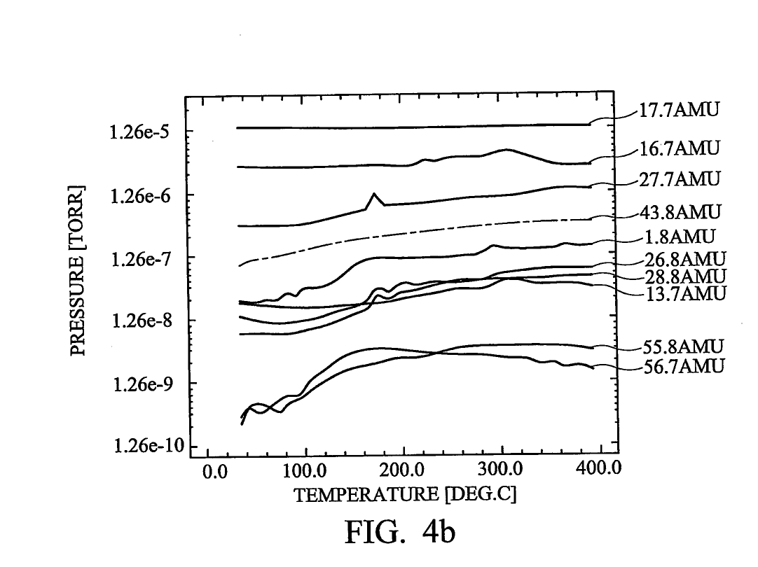

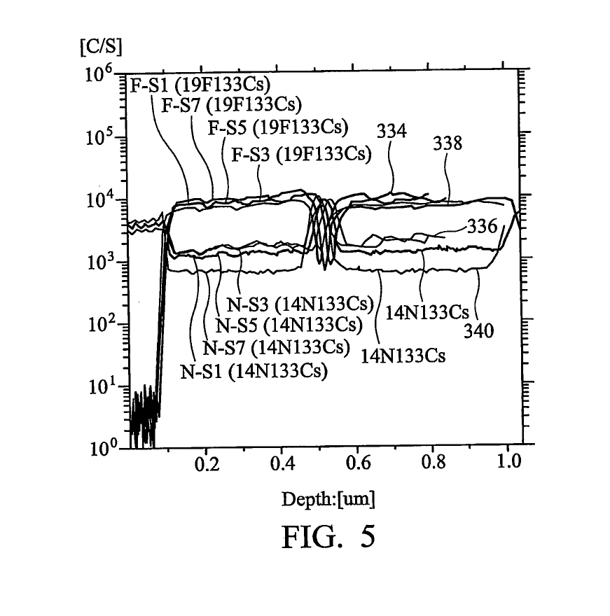

FIGS. 3, 4a, 4b, and 5 show test results of various parameters of a prior art FSG dielectric films compared with the FSG dielectric films 108, 208a and 208b comprising less free F in accordance with embodiments of the present invention. The following analysis was performed on prior art FSG dielectric films and the less free F FSG dielectric films 108, 208a and 208b of the present invention: Fourier Transform Infrared Spectroscopy (FTIR) spectrum analysis (FIG. 3), Thermal Desorption Spectrometer (TDS) comparison (FIGS. 4a and 4b), secondary ion mass spectrometer (SIMS) comparison (FIG. 5), film porosity check, wet etching rate, and electrical performance. The less free F FSG dielectric films 1108, 208a and 208b described herein exhibited better performance than prior art films in these tests.

FIG. 3 shows results of a FTIR spectrum test of a prior art FSG dielectric film at 332, and of the less free F FSG dielectric films 108, 208a and 208b in accordance with an embodiment of the present invention, at 330. FTIR measures the infrared intensity versus wavelength (wave numbers) of light. Infrared spectroscopy detects the vibration characteristics of chemical functional groups in a sample. When an infrared light interacts with the material under test, chemical bonds will stretch, contract and bend. As a result, a chemical functional group tends to adsorb infrared radiation in a specific wavenumber range, regardless of the structure of the rest of the molecule.

The graph shown in FIG. 3 illustrates that the less free F FSG dielectric films 108, 208a and 208b shows a more obvious SiF peak than the prior art FSG dielectric film. This indicates that the less free F FSG dielectric films 108, 208a and 208b have more pure SiF bonding and lower free F. In Table 1, the free F % comparison of the prior art FSG dielectric film and the FSG dielectric films 108, 208a and 208b of the present invention is shown. Free F % is calculated in Table 1 by subtracting the XRF (x-ray fluorescence spectrometry), which is an instrumental means to detect the elemental composition of the homogeneous obsidian. XRF detects fluorine that is bonded with silicon and non-bonded with silicon: in other words, XRF detects the total fluorine concentration of the film.

TABLE 1

| | F by | F by | Free F |
|---|---|---|---|
| | FTIR | XRF | % |
| Prior art film | 5.51% | 8.20% | 32.80% |
| less free F FSG film | 5.56% | 6.45% | 17.90% |
| 108/208a/208b | | | |

In Table 1, XRF=bonded F+non-bonded F, FTIR=bonded F, and Free F=non-bonded F=XRF—FTIR. The “free” F % is the % of F atoms that have not bonded to silicon. The free F % atoms typically are in an ion state (F−).

FIG. 4a shows TDS test results for a prior art FSG dielectric film for a range of partial pressures and temperatures. FIG. 4b shows TDS test results for the less free F FSG dielectric films 108, 208a and 208b in accordance with an embodiment of the present invention over the same pressures and temperatures as the prior art film was tested in FIG. 4a. The TDS data shows that the prior art FSG dielectric film exhibited more F out-gassing than the less free F FSG dielectric films 108, 208a and 208b of the present invention, when temperature was above 200° C. The test results shown in FIGS. 4a and 4b also indicate that the novel less free F FSG dielectric films 108, 208a and 208b of embodiments of the present invention are much more stable than prior art FSG dielectric film. Note that in FIGS. 4a and 4b, “AMU” represents “atomic mass unit”.

FIG. 5 shows a SIMS comparison between a prior art FSG dielectric film and a film 108, 208a or 208b in accordance with an embodiment of the present invention. The novel less free F FSG dielectric film 108, 208a or 208b exhibited a low N and free F count, which is achieved by depositing the less free F FSG dielectric film 108, 208a or 208b using a low SiF₄:SiH₄ ratio and a low N₂O flow rate. In FIG. 5, “14N133Cs” indicates Nitrogen, and “19F133Cs” indicates Fluorine, as examples.

High N counts and high free F were found in the prior art PEFSG dielectric film, as can be seen in the graph at 334 and 336. The less free F FSG dielectric film 108, 208a or 208b of the present invention exhibited low N counts and free F in the less free F PEFSG dielectric film 108, 208a and 208b, as can be seen in the graph at 338 and 340.

Wet etching rate test results for the less free F FSG dielectric films 108, 208a and 208b of the present invention show a slower etching rate in the same etching condition for a thermal oxide. In general, an etching ratio of present invention FSG film 108, 208a and 208b to conventional FSG film was found to be about 0.4 to about 0.7. Dry etch rate test results for a prior art FSG dielectric film compared to test results of a dry etch rate for the less free F FSG dielectric film 108, 208a and 208b of embodiments of the present invention show a similar trend as the wet etching rate test. Both the wet etching rate and the dry etching rate were found to be lower for the novel less free F FSG dielectric film 108, 208a and 208b of the present invention, which is advantageous because the etching of the film 108, 208a and 208b can be better controlled in the manufacturing process. The etching test results indicate that the less free F FSG dielectric film 108, 208a and 208b is more dense and stronger than prior art films, solving the problems in the prior art of FSG films being too porous.

Compared to prior art FSG dielectric films, a tighter Rc-Via performance is achieved for the FSG dielectric film 108, 208a and 208b comprising less free F in accordance with an embodiment of the present invention. (Rc-Via is the resistivity of a via measured in units of ohms, for example.)

Embodiments of the present invention have been described herein with reference to damascene methods of forming conductive lines. However, the less free F FSG dielectric films 108, 208a and 208b described herein also may be used in structures having conductive lines formed using a subtractive etch process. For example, a conductive material may be deposited over a workpiece, and the conductive material may be patterned using lithography techniques to form conductive lines in the conductive material. The less free F FSG dielectric material 108, 208a and 208b described herein may then be deposited over the patterned conductive material. Any excess less free F FSG dielectric material 108, 208a and 208b may then be removed from over the conductive lines. Barrier layers may also be used in such a subtractive etch process to form conductive lines, for example.

Advantages of embodiments of the invention include providing an FSG dielectric film 108, 208a and 208b for use as a dielectric material layer in semiconductor devices having less free F. The FSG dielectric film 108, 208a and 208b is less porous, is more stable and has an improved film quality than prior art FSG dielectric films.

Although embodiments of the present invention and their advantages have been described in detail, it should be understood that various changes, substitutions and alterations can be made herein without departing from the spirit and scope of the invention as defined by the appended claims. For example, it will be readily understood by those skilled in the art that many of the features, functions, processes, and materials described herein may be varied while remaining within the scope of the present invention. Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or. achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. A semiconductor device, comprising:
a workpiece; and
a fluorine containing dielectric film formed over the workpiece, wherein the fluorine containing dielectric film comprises a wet etching rate ratio to a thermal oxide of less than about 15 by HF.

2. The semiconductor device according to claim 1, wherein the fluorine containing dielectric film comprises about 25% or less free fluorine (F).

3. The semiconductor device according to claim 1, wherein the fluorine containing dielectric film comprises a wet etching rate of less than about 300 A/minute by 100:1 HF or less than about 700 Å/minute by 50:1 HF.

4. The semiconductor device according to claim 1, wherein the fluorine containing dielectric film comprises a nitrogen (N) concentration of about 1000 counts/second (c/s) or less.

5. The semiconductor device according to claim 1, wherein the fluorine containing dielectric film comprises a dielectric constant of about 3.8 or less.

6. The semiconductor device according to claim 1, wherein the fluorine containing dielectric film comprises a thickness of about 2,000 A to about 15,000 Å.

7. The semiconductor device according to claim 1, further comprising a first diffusion barrier layer disposed between the workpiece and the fluorine containing dielectric film.

8. The semiconductor device according to claim 7, wherein the first diffusion barrier layer comprises a thickness of about 600 Å or less.

9. The semiconductor device according to claim 7, wherein the first diffusion barrier layer comprises nitrogen-containing material.

10. The semiconductor device according to claim 7, wherein the first diffusion barrier layer comprises carbon-containing material.

11. The semiconductor device according to claim 7, wherein the first diffusion barrier layer comprises a first thickness, wherein the first diffusion barrier layer comprises an F diffusion depth of about ⅔ the first thickness adjacent and abutting the fluorine containing dielectric film.

12. The semiconductor device according to claim 7, wherein the F concentration in the F diffusion depth of the first diffusion barrier layer comprises about 64% F or less.

13. The semiconductor device according to claim 1, further comprising at least one conductive line disposed within the fluorine containing dielectric film.

14. The semiconductor device according to claim 13, further comprising a second diffusion barrier layer disposed between the fluorine containing dielectric film and the at least one conductive line.

15. The semiconductor device according to claim 14, wherein the second diffusion barrier layer comprises a thickness of about 600 Å or less.

16. The semiconductor device according to claim 14, wherein the second diffusion barrier layer comprises nitrogen-containing material.

17. The semiconductor device according to claim 14, wherein the second diffusion barrier layer comprises carbon-containing material.

18. The semiconductor device according to claim 14, wherein the second diffusion barrier layer comprises refractory metal.

19. The semiconductor device according to claim 14, wherein the second diffusion barrier layer comprises a second thickness, wherein the second diffusion barrier layer comprises an F diffusion depth of about ⅔ the second thickness adjacent and abutting the fluorine containing dielectric film.

20. The semiconductor device according to claim 19, wherein the F concentration in the F diffusion depth of the second diffusion barrier layer comprises about 64% F or less.

21. The semiconductor device according to claim 14, further comprising a first diffusion barrier layer disposed between the workpiece and the fluorine containing dielectric film.

22. The semiconductor device according to claim 21, wherein the first diffusion barrier layer comprises a thickness of about 600 A or less, and wherein the first diffusion barrier layer comprises nitrogen-containing material.

23. The semiconductor device according to claim 21, wherein the first diffusion barrier layer comprises a thickness of about 600 A or less, and wherein the first diffusion barrier layer comprises carbon-containing material.

24. The semiconductor device according to claim 21, wherein the first diffusion barrier layer comprises a first thickness, wherein the first diffusion barrier layer comprises an F diffusion depth of about ⅔ the first thickness adjacent and abutting the fluorine containing dielectric film, wherein the F concentration in the F diffusion depth of the first diffusion barrier layer comprises about 64% F or less.

25. The semiconductor device according to claim 13, wherein the at least one conductive line includes at least one via.

26. A semiconductor device, comprising:
a workpiece;
a device formed within the workpiece;
a fluorine containing dielectric film formed over the workpiece, the fluorine containing dielectric film comprising a wet etching rate of less than about 300 Å/minute by 100:1 HF at a temperature of about 21 degrees C. to about 75 degrees C. and a dielectric constant of about 3.8 or less; and
at least one conductive line disposed within the fluorine containing dielectric film.

27. The semiconductor device according to claim 26, wherein the fluorine containing dielectric film comprises a nitrogen (N) concentration of about 1000 counts/second (c/s) or less.

28. The semiconductor device according to claim 26, wherein the fluorine containing dielectric film comprises a thickness of about 2,000 Å to about 15,000 Å.

29. The semiconductor device according to claim 26, further comprising a first diffusion barrier layer disposed between the workpiece and the fluorine containing dielectric film, wherein the first diffusion barrier layer comprises a thickness of about 600 Å or less.

30. The semiconductor device according to claim 29, wherein the first diffusion barrier layer comprises nitrogen-containing material.

31. The semiconductor device according to claim 29, wherein the first diffusion barrier layer comprises carbon-containing material.

32. The semiconductor device according to claim 29, wherein the first diffusion barrier layer comprises a first thickness, wherein the first diffusion barrier layer comprises an F diffusion depth of about ⅔ the first thickness adjacent and abutting the fluorine containing dielectric film.

33. The semiconductor device according to claim 32, wherein the F concentration in the F diffusion depth of the first diffusion barrier layer comprises about 64% F or less.

34. The semiconductor device according to claim 26, further comprising a second diffusion barrier layer disposed between the fluorine containing dielectric film and the at least one conductive line, wherein the second diffusion barrier layer comprises a thickness of about 600 Å or less.

35. The semiconductor device according to claim 34, wherein the second diffusion barrier layer comprises nitrogen-containing material.

36. The semiconductor device according to claim 34, wherein the second diffusion barrier layer comprises carbon-containing material.

37. The semiconductor device according to claim 34, wherein the second diffusion barrier layer comprises refractory metal.

38. The semiconductor device according to claim 34, wherein the second diffusion barrier layer comprises a first thickness, wherein the second diffusion barrier layer comprises an F diffusion depth of about ⅔ the first thickness adjacent and abutting the fluorine containing dielectric film.

39. The semiconductor device according to claim 38, wherein the F concentration in the F diffusion depth of the second diffusion barrier layer comprises about 64% F or less.

40. A method of fabricating a semiconductor device, the method comprising:
providing a workpiece; and
forming a fluorine containing dielectric film over the workpiece, wherein the fluorine containing dielectric film comprises about 25% or less free fluorine (F).

41. The semiconductor device according to claim 40, wherein the fluorine containing dielectric film comprises a wet etching rate ratio to a thermal oxide of less than about 15 by HF.

42. The method according to claim 40, further comprising etching the fluorine containing dielectric film, wherein etching the fluorine containing dielectric film comprises a wet etching rate of less than about 300 Å/minute by 100:1 HF or less than about 700 Å/minute by 50:1 HF.

43. The method according to claim 40, wherein forming the fluorine containing dielectric film comprises forming a fluorine containing dielectric film comprising a nitrogen (N) concentration of about 1000 counts/second (c/s) or less.

44. The method according to claim 40, wherein forming the fluorine containing dielectric film comprises forming a fluorine containing dielectric film comprising a dielectric constant of about 3.8 or less.

45. The method according to claim 40, wherein forming the fluorine containing dielectric film comprises forming a fluorine containing dielectric film comprising a low out-gassing rate and a partial pressure of fluorine of less than about 5×10⁻⁸ Torr at a temperature of about 25 to 400° C. in a vacuum environment.

46. The method according to claim 40, wherein forming the fluorine containing dielectric film comprises forming a fluorine containing dielectric film comprising a thickness of about 2,000 Å to about 15,000 Å.

47. The method according to claim 40, wherein forming the fluorine containing dielectric film comprises placing the workpiece into a deposition chamber, and introducing SiF₄:SiH₄ at a reaction condition ratio of about 2.5 or less.

48. The method according to claim 47, wherein the pressure in the deposition chamber comprises about 3 Torr or less.

49. The method according to claim 47, wherein the radio frequency (RF) applied to the deposition chamber comprises about 500 watts to 5000 watts.

50. The method according to claim 47, wherein an ambient gas in the deposition chamber comprises oxygen based gas introduced at a flow rate of about 5000 to 15,000 sccm.

51. The method according to claim 50, wherein the oxygen based gas comprises N₂O.

52. The method according to claim 50, wherein the oxygen based gas comprises NO or NO₂.

53. The method according to claim 50, wherein the oxygen based gas comprises O₂, O₃, or CO₂.

54. The method according to claim 40, wherein forming the fluorine containing dielectric film comprises plasma enhanced chemical vapor deposition (PECVD) or high-density plasma chemical vapor deposition (HDP CVD).

55. The method according to claim 40, further comprising forming a first diffusion barrier layer over the workpiece, before forming the fluorine containing dielectric film.

56. The method according to claim 55, wherein forming the first diffusion barrier layer comprises forming the first diffusion barrier layer having a thickness of about 600 Å or less.

57. The method according to claim 55, wherein forming the first diffusion barrier layer comprises forming nitrogen-containing material.

58. The method according to claim 55, wherein forming the first diffusion barrier layer comprises forming carbon-containing material.

59. The method according to claim 55, wherein forming the first diffusion barrier layer comprises forming the first diffusion barrier layer having a first thickness, wherein the first diffusion barrier layer comprises an F diffusion depth of about ⅔ the first thickness adjacent and abutting the fluorine containing dielectric film.

60. The method according to claim 59, wherein the F concentration in the F diffusion depth of the first diffusion barrier layer comprises about 64% F or less.

61. The method according to claim 40, further comprising forming at least one conductive line over the workpiece, wherein the at least one conductive line is disposed within the fluorine containing dielectric film.

62. The method according to claim 61, wherein forming the at least one conductive line comprises a subtractive etch process, wherein the at least one conductive line is formed before forming the fluorine containing dielectric film.

63. The method according to claim 61, wherein forming the at least one conductive line comprises a damascene process, wherein the fluorine containing dielectric film is formed before forming the at least one conductive line, wherein forming the at least one conductive line comprises patterning the fluorine containing dielectric film and depositing a conductive material over the fluorine containing dielectric film to form the at least one conductive line.

64. The method according to claim 63, further comprising forming a second diffusion barrier layer over the patterned fluorine containing dielectric film, after patterning the fluorine containing dielectric.

65. The method according to claim 64, wherein forming the second diffusion barrier layer comprises forming a second diffusion barrier layer comprising a thickness of about 600 Å or less.

66. The method according to claim 64, wherein forming the second diffusion barrier layer comprises forming a second diffusion barrier layer comprising nitrogen-containing material.

67. The method according to claim 64, wherein forming the second diffusion barrier layer comprises forming a second diffusion barrier layer comprising carbon-containing material.

68. The method according to claim 64, wherein forming the second diffusion barrier layer comprises forming a second diffusion barrier layer comprising refractory metal.

69. The method according to claim 64, wherein forming the second diffusion barrier layer comprises forming a second diffusion barrier layer comprising a second thickness, wherein the second diffusion barrier layer comprises an F diffusion depth of about ⅔ the second thickness adjacent and abutting the fluorine containing dielectric film.

70. The method according to claim 69, wherein the F concentration in the F diffusion depth of the second diffusion barrier layer comprises about 64% F or less.

71. The method according to claim 63, further comprising pretreating the fluorine containing dielectric film, after patterning the fluorine containing dielectric film.

72. The method according to claim 71, wherein pretreating the fluorine containing dielectric film comprises a plasma treatment.

73. The method according to claim 71, wherein pretreating the fluorine containing dielectric film comprises a rinse in a base environment.

74. The method according to claim 71, wherein pretreating the fluorine containing dielectric film comprises a rinse in an acid environment.

75. The method according to claim 71, wherein pretreating the fluorine containing dielectric film comprises a thermal treatment.

76. The method according to claim 71, wherein pretreating the fluorine containing dielectric film comprises a nitrogen containing ambient treatment.

77. The method according to claim 71, wherein pretreating the fluorine containing dielectric film comprises a hydrogen containing ambient treatment.

78. The method according to claim 61, wherein forming the at least one conductive line comprises a dual damascene process, wherein the fluorine containing dielectric film is formed before forming the at least one conductive line, wherein forming the at least one conductive line comprises patterning the fluorine containing dielectric film and depositing a conductive material over the fluorine containing dielectric film to form the at least one conductive line in the fluorine containing dielectric film, and wherein forming the at least one conductive line includes forming at least one via within the fluorine containing dielectric film.
